(19) United States
(12) Patent Application Publication
(10) Pub. No.: US 2009/0008625 A1
(43) Pub. Date: Jan. 8, 2009

(54) Optoelectronic device

(75) Inventors: Tzong-Liang Tsai, Taichung City (CN); Ming-Huang Hong, Taichung City (TW)

Correspondence Address: SINORICA, LLC, 528 FALLSGROVE DRIVE, ROCKVILLE, MD, 20850, US

(73) Assignee: Huga Optotech Inc.

(21) Appl. No.: 11/998,405

(22) Filed: Nov. 30, 2007

(30) Foreign Application Priority Data
Jul. 6, 2007 (CN) 096124609

(51) Int. Cl. H01L 33/00

(52) U.S. Cl. 257/13; 257/E33.008

(57) ABSTRACT

The present invention provides an optoelectronic device, which includes a substrate having a first surface and a second surface, and an atomization layer located therebetween; a multi-layer semiconductor layer is formed on the first surface of the substrate, which further includes a first semiconductor structure that is formed on the substrate, a second semiconductor structure, and an active layer is located between the first semiconductor structure and the second semiconductor structure.

### BACKGROUND OF THE INVENTION

1. Field of the Invention

The present invention is related to an optoelectronic device, especially related to an optoelectronic device having a substrate with an atomization layer therein to enhance the light-emitting efficiency through changing the lattice structure of the substrate.

2. Background of the Related Art

The crystal property of GaN compound needs to be improved for providing a solution on the issue of lattice matching between sapphire and GaN in a light-emitting layer. In U.S. Pat. No. 5,122,845, shown in FIG. 1, an AlN-based buffer layer 101 is formed between a substrate 100 and GaN compound layer 102, which is microcrystal or polycrystal to improve crystal mismatching between the substrate 100 and the GaN compound layer 102. In U.S. Pat. No. 5,290,393, shown in FIG. 2, an optoelectronic device is a GaN-based compound semiconductor layer 202, such as GaₓAl₁₋ₓN (0<x≦1). However, during the formation of a compound semiconductor layer 202 on a substrate 200 by epi-growth, the lattice structure on the surface of the substrate 200 may influence the quality of a sapphire device. Thus, a buffer layer 201, such as GaₓAl₁₋ₓN, is between the substrate 200 and the compound semiconductor layer 202 to improve lattice mismatching. Furthermore, in U.S. Pat. Nos. 5,929,466 or 5,909,040, shown in FIG. 3, an AlN layer 301 as a first buffer layer is formed on a substrate 300, an InN layer 302 as a second buffer layer is on the AlN layer 301, which may improve lattice mismatching near the substrate 300.

### SUMMARY OF THE INVENTION

In order to solve the problems mentioned above, one of objectives of the present invention utilizes laser to focus energy on a specific depth in a substrate to form the substrate in polycrystal or amorphous structure and form an atomization layer. Thus, light emitted from the upper layer of the substrate may be scattered outside the optoelectronic device, reduce total reflection and enhance optical efficiency.

Another objective of the present invention provides an optoelectronic device of multi-layer structure to reduce lattice mismatching between a light-emitting layer and a first semiconductor structure.

Accordingly, the present invention provides an optoelectronic device includes a substrate with a first surface and a second surface, an atomization layer between the first surface and the second surface; and a multi-layer semiconductor layer on the first surface of the substrate. The multi-layer semiconductor layer includes a first semiconductor structure on the substrate, a second semiconductor structure and an active layer between the first semiconductor structure and the second semiconductor structure.

Accordingly, the present invention provides an optoelectronic device includes a first electrode, a substrate on the first electrode and with a first surface and a second surface, an atomization layer between the first surface and the second surface and a multi-layer semiconductor layer on the first surface of the substrate. The multi-layer semiconductor layer includes a first semiconductor structure on the substrate, a second semiconductor structure and an active layer between the first semiconductor structure and the second semiconductor structure. Moreover, a transparent conductive layer is on the second semiconductor structure. A second electrode is on the transparent conductive layer.

### BRIEF DESCRIPTION OF THE DRAWINGS

FIG. 1 is a cross-sectional diagram illustrating an optoelectronic device in accordance with a prior art.

FIG. 2 is a cross-sectional diagram illustrating an epitaxy wafer in accordance with a prior art.

FIG. 3 is a cross-sectional diagram illustrating an optoelectronic device in accordance with a prior art.

FIG. 4A and FIG. 4B are cross-sectional diagrams illustrating optoelectronic semiconductor devices in accordance with the present invention.

FIG. 5A and FIG. 5B are schematically cross-sectional diagrams illustrating optoelectronic devices in accordance with the present invention.

FIG. 6A and FIG. 6B are schematically cross-sectional diagrams illustrating optoelectronic devices in accordance with the present invention.

FIG. 7A and FIG. 7B are schematically cross-sectional diagrams illustrating optoelectronic devices in accordance with the present invention.

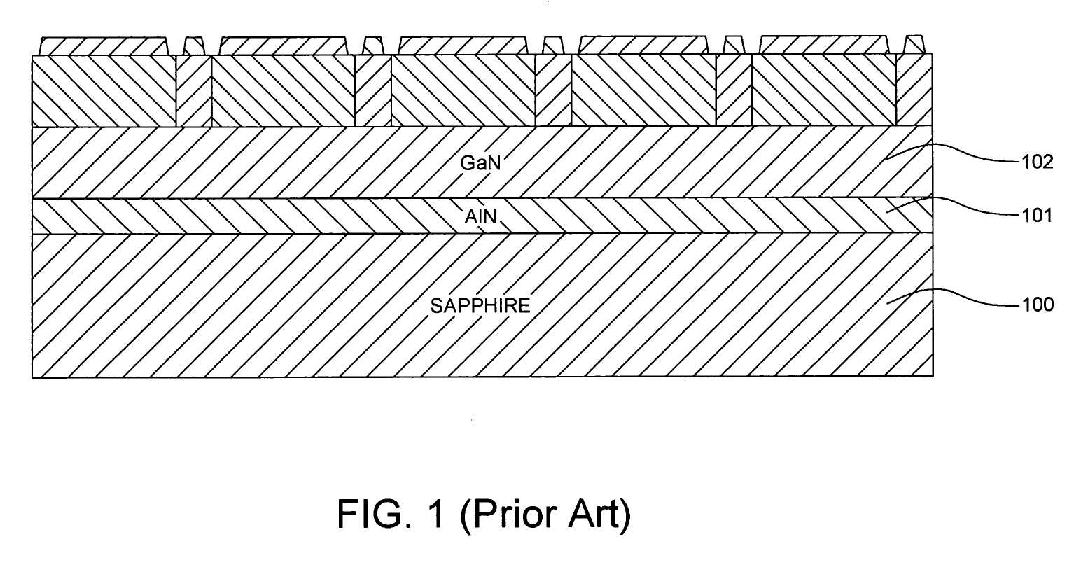

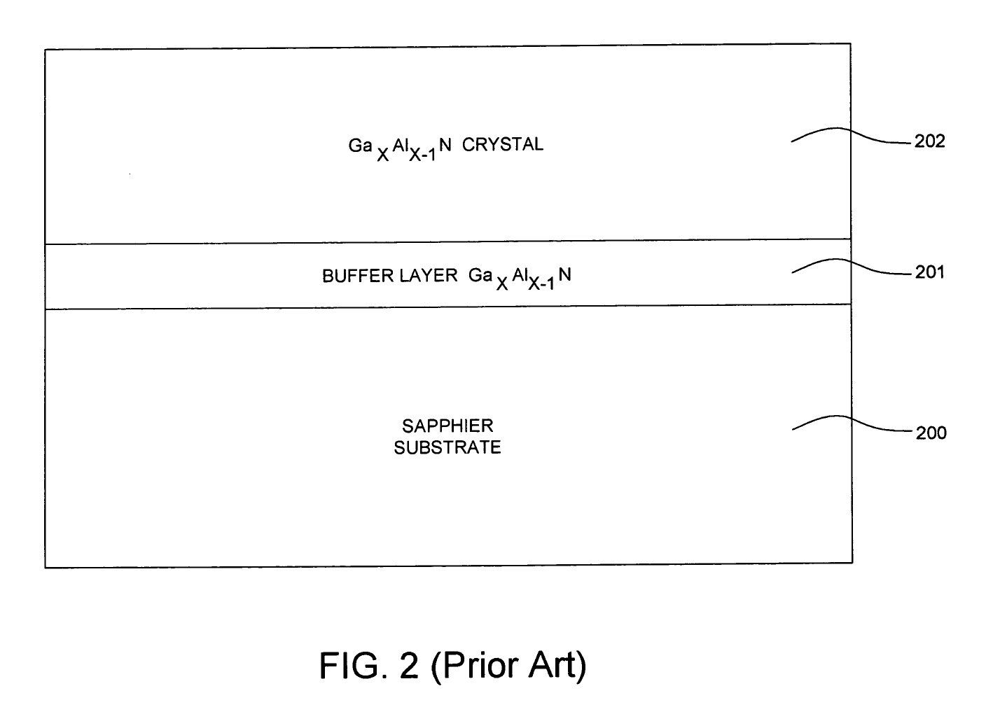

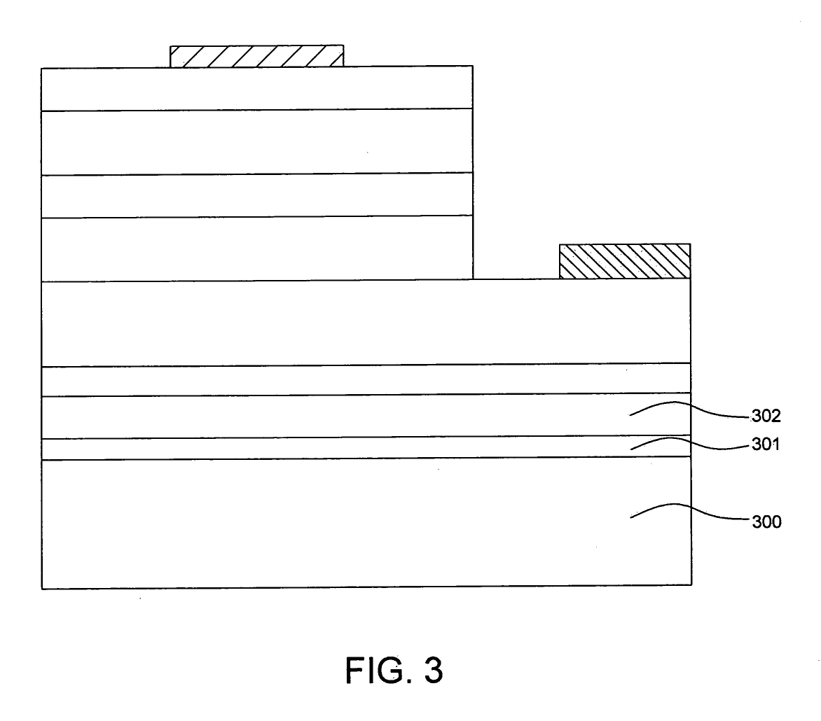

### DETAILED DESCRIPTION OF THE INVENTION

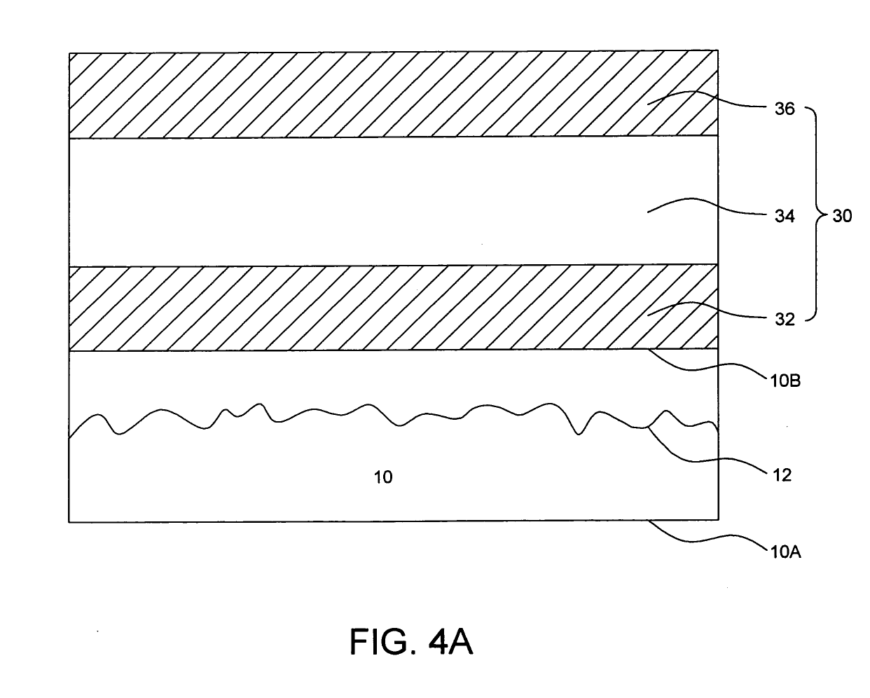

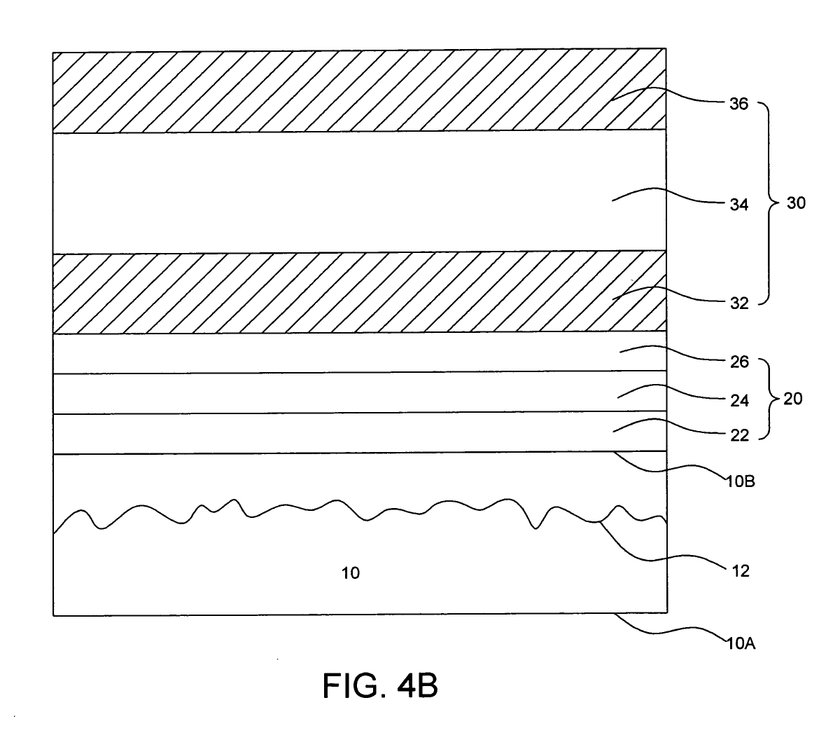

FIG. 4A is a cross-sectional diagram illustrating an optoelectronic semiconductor device in accordance with the present invention. An exemplary optoelectronic semiconductor device includes a substrate 10 with a first surface 10A and a second surface 10B, an atomization layer 12 between the first surface 10A and the second surface 10B, and a multi-layer semiconductor layer 30. The multi-layer semiconductor layer 30 at least includes a first semiconductor structure 32, a second semiconductor structure 36 and an active layer 34 between the first semiconductor structure 32 and the second semiconductor structure 36. In one embodiment, the first semiconductor structure 32 may be an N-type semiconductor layer, and the second semiconductor structure 36 may be a P-type one. The active layer 34 may be a multiple quantum well (MQW) or a quantum well (QW).

In this embodiment, laser lithography with focusing energy is applied to the substrate 10 so as to form an atomization layer 12 in the interior of the substrate 10. The atomization layer 12 in the substrate 10 is configured for scattering light from an emitting device on the substrate 10 out of the emitting device so as to reduce total reflection and improve light utility.

Moreover, the surface of the substrate 10 is not destroyed during the laser lithography, as well as is the quality of sequential epitaxy growth. Furthermore, the energy generated by the laser may enhance rearrangement of crystal structure in the interior of the substrate 10 (i.e. between the first surface 10A and the second surface 10B). The methods of crystal arrangement may be started from polycrystal or amorphous structure, which may enhance the efficiency of an optoelectronic device. The depth of the atomization layer 12 may be optimized by the focus and wavelength of the laser. For example, the laser as a light source is of the wavelength of 355 nm and the frequency between 70 kHz and 250 kHz. An adaptive optic focusing module equipped with the laser is employed on the position in the depth about 10 to 30 um under the surface of the substrate 10 to form the atomization layer of the thickness of about 3 um. The first semiconductor structure (N-type GaN semiconductor layer) 32, the active layer 34 and the second semiconductor structure (P-type GaN semiconductor layer) 36, which constitute the multi-layer semiconductor layer 30, are sequentially formed on the substrate 10 by epitaxy formation. The multi-layer semiconductor layer 30 on the substrate 10 with the atomization layer 12 performs light-emitting efficiency of 15% higher than one of a general substrate.

Furthermore, according to the present invention, the optical semiconductor structure further includes a buffer layer 20 formed between the substrate 10 and the multi-layer semiconductor layer 30, shown as FIG. 4B. The buffer layer 20 may be a GaN-based compound layer, or the first nitride compound layer 22/V-II group compound layer 24/the second nitride compound layer 26. The first nitride compound layer 22 may be an AlInGaN layer, InGaN layer, AlGaN layer or AlInN layer. The second nitride compound layer 26 may be selected from the groups consisting of an AlGaN and GaN layer. The II group in V-II group compound layer 24 may be selected from the groups consisting of Be, Mg, Ca, Sr, Ba, Ra, Zn, Cd and Hg. The V group in V-II group compound layer 24 may be selected from the groups consisting of N, P, As Sb and Bi.

Thus, the buffer layer 20, which is consisted of the first nitride compound layer 22/V-II group compound layer 24/the second nitride compound layer 26 is a multi-strain buffer layer structure configured to be an initial layer for a sequential epi stacked layer by epi-growth method. Furthermore, there is good lattice match between the the buffer layer 20 and the first semiconductor structure 32 of the multi-layer semiconductor layer 30.

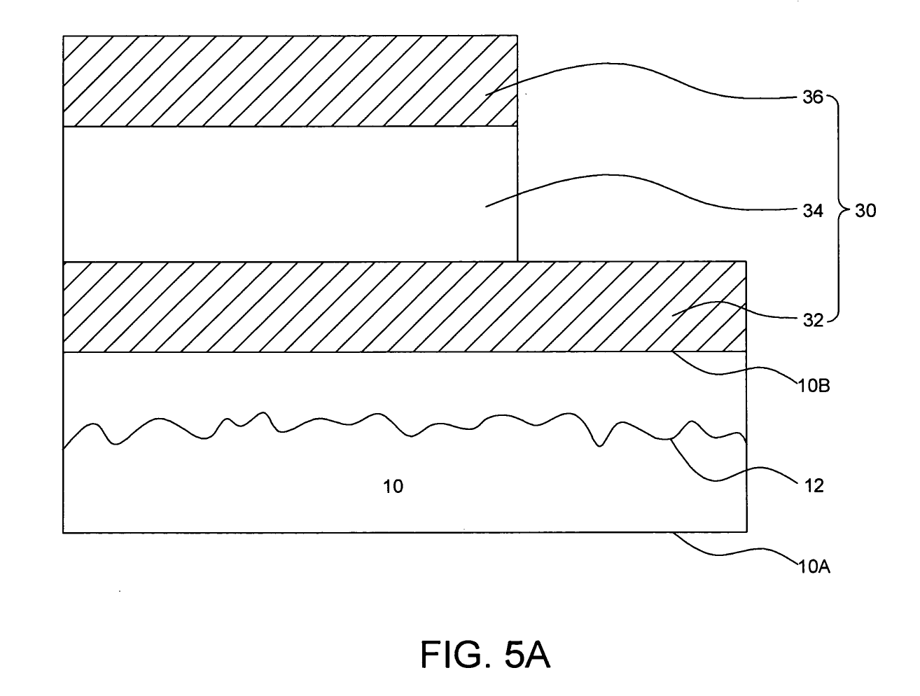

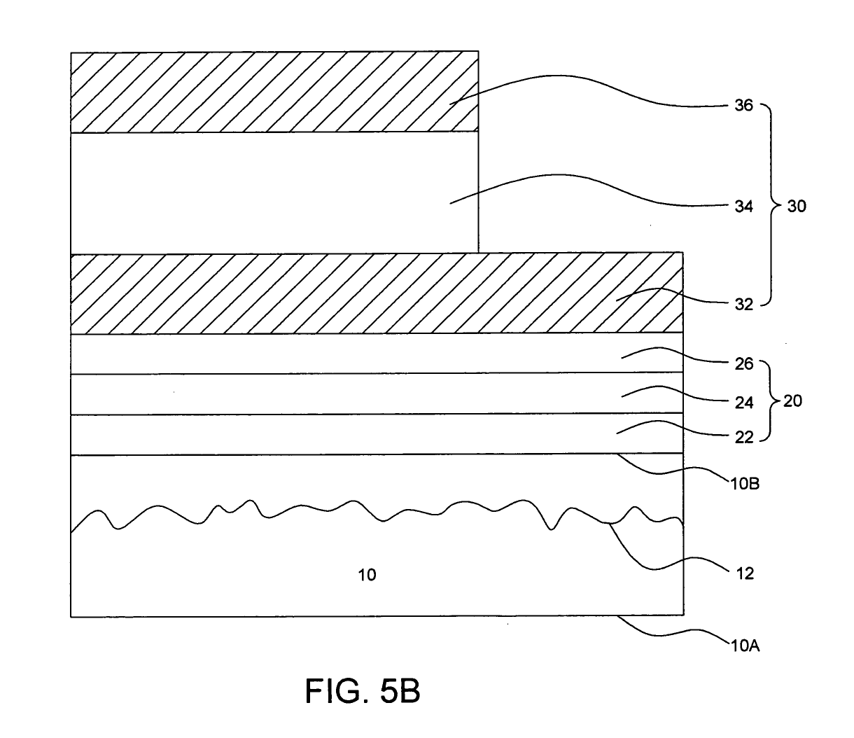

Next, FIG. 5A and FIG. 5B are schematically cross-sectional diagrams illustrating optoelectronic devices in accordance with the present invention. In FIG. 5A and FIG. 5B, the formation, structure and characteristics for the substrate 10 and the multi-layer semiconductor layer 30 are same as ones in FIG. 4A and FIG. 4B, which are not repeatedly illustrated herein. The difference in them is that the first semiconductor structure 32, the active layer 34 and the second semiconductor structure 36 are subsequently formed by the epi-growth on the substrate 10 with the atomization layer 12. Then the portions of the first semiconductor structure 32, the active layer 34 and the second semiconductor structure 36 are removed by etching method to expose the portion of the first semiconductor structure 32 for forming the structure of an optoelectronic device.

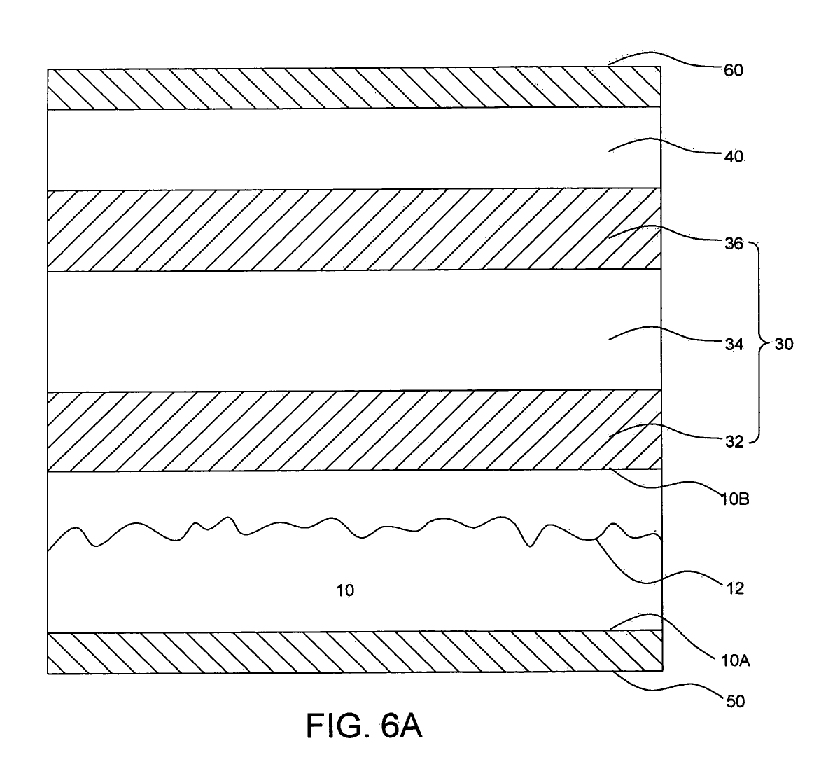

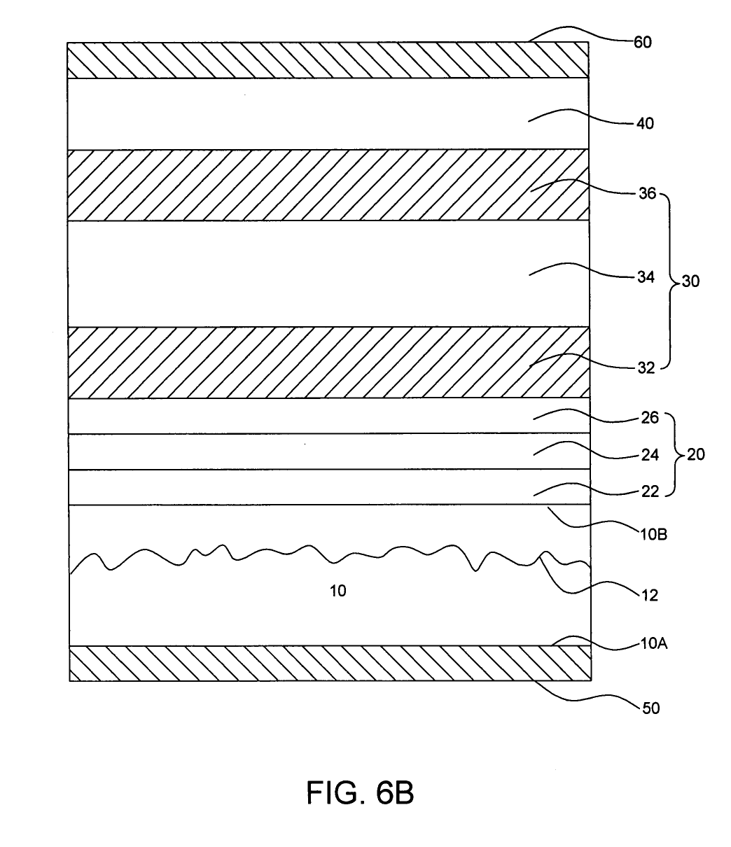

Next, FIG. 6A is a schematically cross-sectional diagram illustrating optoelectronic devices in accordance with the present invention. In FIG. 6A, the formation, structure and characteristics for the structures are same as ones in FIG. 4A, which are not repeatedly illustrated herein. In FIG. 6A, an optoelectronic device includes a first electrode 50; a substrate 10 with an atomization layer 12 on the first electrode 50; a multi-layer semiconductor layer 30 on the substrate 10. The multi-layer semiconductor layer 30 includes a first semiconductor structure 32, a second semiconductor structure 36 and an active layer 34 between the first semiconductor structure 32 and the second semiconductor structure 36. Next, a transparent conductive layer 40 is formed on the multi-layer semiconductor layer 30 and a second electrode 60 is formed on the transparent conductive layer 40. In the embodiment, first, an epitaxy wafer, which performs the formation of multi-layer semiconductor layer 30 on the substrate 10, is moved out from a reactor chamber of room temperature. Next, a mask pattern is transferred to the second semiconductor structure 36 of the multi-layer semiconductor layer 30 and then performed by reactive ion etching. Next, the transparent conductive layer 40 covers over the whole second semiconductor structure 36 and has a thickness of about 2500 Angstroms. The material of the transparent conductive layer 40 is selected from the groups consisting of: Ni/Au, NiO/Au, Ta/Au, TiWN, TN, Indium Tin Oxide, Chromium Tin Oxide, Antinomy doped Tin Oxide, Zinc Aluminum Oxide and Zinc Tin Oxide.

Next, the second electrode 60 forms on the transparent conductive layer 40 and has a thickness of 2000 um. In the embodiment, the second semiconductor structure 36 is a P-type nitride semiconductor layer, such as Au/Ge/Ni, Ti/Al, Tl/Al/Ti/Au or Cr/Au alloy or combination thereof. Finally, the first electrode 50 forms on the substrate 10, such as Au/Ge/Ni, Ti/Al, Ti/Al/Ti/Au, Cr/Au alloy or W/Al alloy. It is noted that the first electrode 50 and the second electrode 60 are formed by suitable conventional methods, which are not mentioned herein again.

Furthermore, a buffer layer 20 may further form on the substrate 10 with the atomization layer 12, shown in FIG. 6B. The buffer layer 20 may be a GaN-based compound layer, or the first nitride compound layer 22/V-II group compound layer 24/the second nitride compound layer 26. The buffer layer 20 configured to be an initial layer for a sequential epi-stacked layer by epi-growth method. Furthermore, there is good lattice match between the buffer layer 20 and the first semiconductor structure 32 of the multi-layer semiconductor layer 30 to form nitride semiconductor in good qualities.

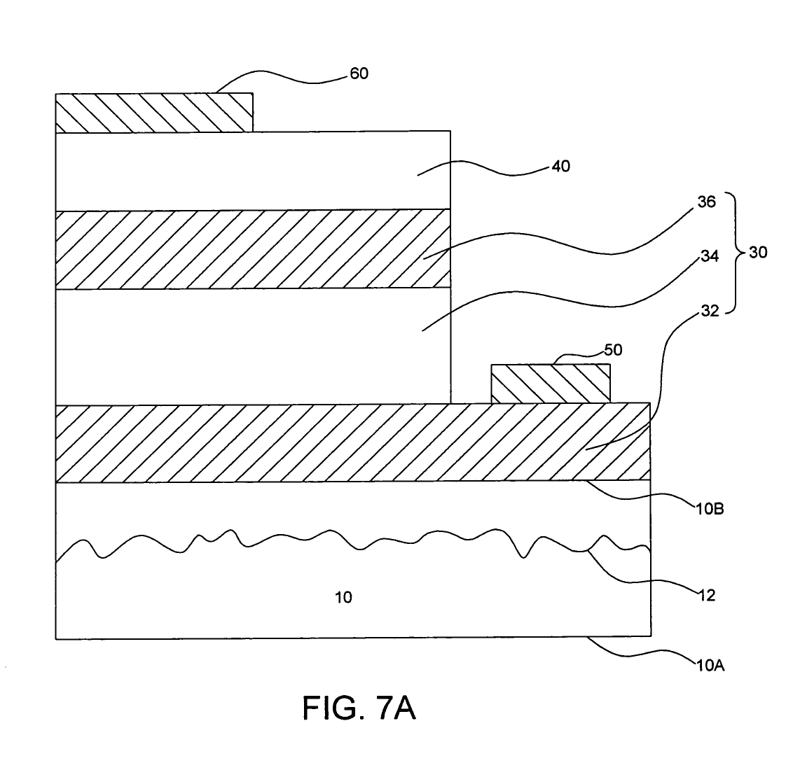

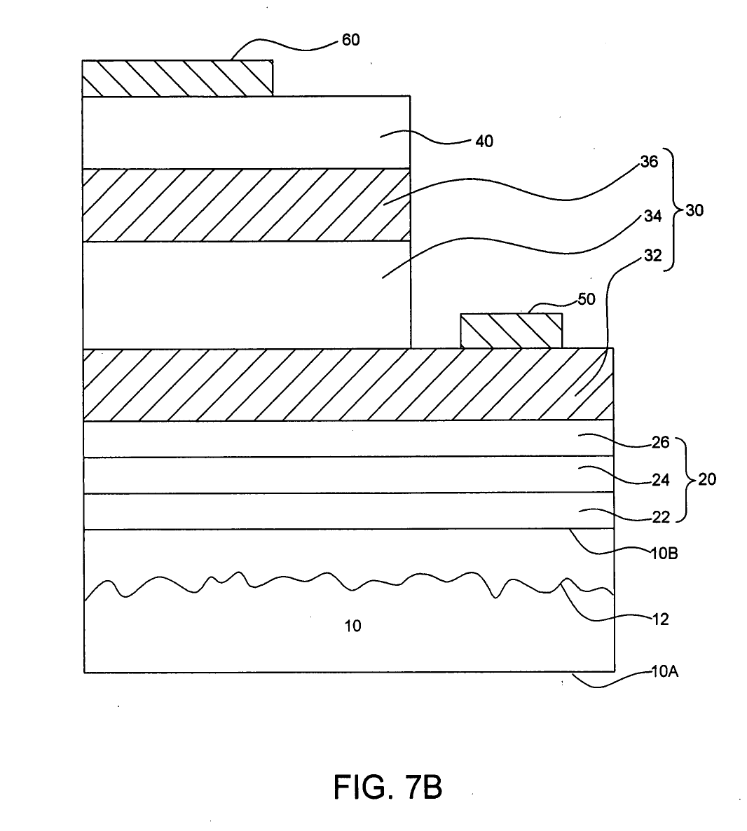

FIG. 7A is a cross-sectional diagram illustrating another optoelectronic device in accordance with the present invention. In FIG. 7A, the formation, structure and characteristics for the structures are same as ones in FIG. 6A, which are not repeatedly illustrated herein. In FIG. 7A, an optoelectronic device includes the substrate 10 with the atomization layer 12, the multi-layer semiconductor layer 30 on the substrate 10. The multi-layer semiconductor layer 30 includes a first semiconductor structure 32, an active layer 34 and a second semiconductor structure 36. Then the portions of the first semiconductor structure 32, the active layer 34 and the second semiconductor structure 36 are removed by etching method to expose the portion of the first semiconductor structure 32. Herein, the first portion of the first semiconductor structure 32 means the portion covered by the active layer 34 and the second semiconductor structure 36. The second portion of the first semiconductor structure 32, which is away from the first portion, means an exposed portion. Next, a transparent conductive layer 40 is formed on the multi-layer semiconductor layer 30 and a second electrode 60 is formed on the transparent conductive layer 40.

Similarly, Furthermore, a buffer layer 20 may further form on the substrate 10 with the atomization layer 12, shown in FIG. 6B. The buffer layer 20 may be a GaN-based compound layer, or the first nitride compound layer 22/V-II group compound layer 24/the second nitride compound layer 26. The buffer layer 20 configured to be an initial layer for a sequential epi stacked layer by epi-growth method. Furthermore, there is good lattice match between the buffer layer 20 and the first semiconductor structure 32 of the multi-layer semiconductor layer 30 to form nitride semiconductor in good qualities.

Obviously, according to the illustration of embodiments aforementioned, there may be modification and differences in the present invention. Thus it is necessary to understand the addition of claims. In addition of detailed illustration aforementioned, the present invention may be broadly applied to other embodiments. Although the present invention has been explained in relation to its preferred embodiment, it is to be understood that other modifications and variation can be made without departing the spirit and scope of the invention as hereafter claimed.

What is claimed is:

1. An optoelectronic semiconductor epi-structure, comprising:
a substrate with a first surface and a second surface, and an atomization layer between said first surface and said second surface; and
a multi-layer semiconductor layer on said first surface of said substrate, wherein said multi-layer semiconductor layer comprises:
a first semiconductor structure on said substrate;
a second semiconductor structure; and
an active layer between said first semiconductor structure and said second semiconductor structure.

2. The optoelectronic semiconductor epi-structure according to claim 1, wherein a thickness of said atomization layer is not less than 10 Angstroms.

3. The optoelectronic semiconductor epi-structure according to claim 1, further comprising a buffer layer comprising a first nitride layer/a V-II group compound layer/a second nitride layer between said substrate and said multi-layer semiconductor layer.

4. The optoelectronic semiconductor epi-structure according to claim 3, wherein said buffer layer comprises an MgN layer.

5. The optoelectronic semiconductor epi-structure according to claim 1, wherein said first semiconductor structure comprises a first portion away from an exposed second portion.

6. The optoelectronic semiconductor epi-structure according to claim 1, wherein said active layer is a multiple quantum well (MQW) or a quantum well (QW).

7. The optoelectronic semiconductor epi-structure according to claim 6, wherein said multiple quantum well (MQW) has an uneven surface.

8. An optoelectronic device, comprising:
a first electrode;
a substrate on said first electrode and with a first surface and a second surface, and an atomization layer between said first surface and said second surface;
a multi-layer semiconductor layer on said first surface of said substrate, wherein said multi-layer semiconductor layer comprises:
a first semiconductor structure on said substrate;
a second semiconductor structure; and
an active layer between said first semiconductor structure and said second semiconductor structure;
a transparent conductive layer on said second semiconductor structure; and
a second electrode on said transparent conductive layer.

9. The optoelectronic device according to claim 8, wherein a thickness of said atomization layer is not less than 10 Angstroms.

10. The optoelectronic device according to claim 8, further comprising a buffer layer between said substrate and said multi-layer semiconductor layer.

11. The optoelectronic device according to claim 8, wherein said buffer layer comprises a V-II group compound layer.

12. The optoelectronic device according to claim 11, wherein said buffer layer comprises an MgN layer.

13. The optoelectronic device according to claim 8, wherein said active layer is a multiple quantum well (MQW) which has an uneven surface.

14. An optoelectronic device, comprising:
a substrate with a first surface and a second surface, and an atomization layer between said first surface and said second surface;
a first semiconductor structure on said substrate and having a first portion and an exposed second portion;
a first electrode on said second portion of said first semiconductor structure;
an active layer on said first portion of said first semiconductor;
a second semiconductor structure on said active layer;
a transparent conductive layer on said second semiconductor structure; and
a second electrode on said transparent conductive layer.

15. The optoelectronic device according to claim 14, wherein a thickness of said atomization layer is not less than 10 Angstroms.

16. The optoelectronic device according to claim 14, further comprising a buffer layer between said substrate and said first semiconductor structure.

17. The optoelectronic device according to claim 14, wherein said buffer layer comprises a V-II group compound layer.

18. The optoelectronic device according to claim 14, wherein said buffer layer comprises an MgN layer.

19. The optoelectronic device according to claim 14, wherein said active layer is a multiple quantum well (MQW) which has an uneven surface.

20. The optoelectronic device according to claim 14, wherein a material of said transparent conductive layer is made from a material selected from the groups consisting of: Ni/Au, NiO/Au, Ta/Au, TiWN, TiN, Indium Tin Oxide, Chromium Tin Oxide, Antinomy doped Tin Oxide, Zinc Aluminum Oxide, and Zinc Tin Oxide.
